(19) United States
(12) Patent Application Publication
(10) Pub. No.: US 2021/0219431 A1
(43) Pub. Date: Jul. 15, 2021

(54) OPTOELECTRONIC COMPONENT AND FABRICATION METHOD THEREOF

(71) Applicant: HUAWEI TECHNOLOGIES CO., LTD., Shenzhen (CN)

(72) Inventors: Wenjun SHI, Wuhan (CN); Zhiwei LI, Wuhan (CN); Qiang ZHANG, Wuhan (CN); Xiaohui LI, Dongguan (CN); Enbo ZHOU, Dongguan (CN)

(21) Appl. No.: 17/206,568

(22) Filed: Mar. 19, 2021

Related U.S. Application Data
(63) Continuation of application No. PCT/CN2018/106672, filed on Sep. 20, 2018.

(51) Int. Cl. H05K 1/18; H05K 3/32; H01S 5/042; H03H 7/38

(52) U.S. Cl. CPC H05K 1/18; H05K 3/32; H01S 5/042; H03H 7/383; H05K 2201/10015; H05K 2201/10378; H05K 2201/10106; H05K 2201/10121; H05K 2201/10492; H05K 2201/10287; H05K 2201/1003

(57) ABSTRACT

Embodiments of this application disclose an optoelectronic component and a fabrication method thereof. The optoelectronic component includes a capacitor, an inductor, a carrier component, and an optoelectronic element, where the capacitor, the inductor, and the optoelectronic element are all disposed on the carrier component. The inductor and the capacitor are configured to form a resonant circuit, where a resonance frequency of the resonant circuit is correlated with a signal output frequency of the optoelectronic element. A first electrode of the optoelectronic element is connected to a first electrode of the carrier component through the inductor, and a second electrode of the optoelectronic element is connected to a second electrode of the carrier component. A first electrode of the capacitor is connected to the first electrode of the carrier component, and a second electrode of the capacitor is connected to the second electrode of the carrier component.

### CROSS-REFERENCE TO RELATED APPLICATIONS

This application is a continuation of International Application No. PCT/CN2018/106672, filed on Sep. 20, 2018, the disclosure of which is hereby incorporated by reference in its entirety.

### TECHNICAL FIELD

This application relates to the field of optoelectronics, and in particular, to an optoelectronic component and a fabrication method thereof.

### BACKGROUND

Packaging an optoelectronic element means forming an optoelectronic component with stable functional performance by the optoelectronic element through electric coupling, device fixation, sealing, or the like. The optoelectronic element may be a laser diode (LD), a distributed feedback laser (DFB), an electro-absorption modulated laser (EML), a Fabry-Perot laser (FP), or the like.

Because an impedance of the optoelectronic element is relatively low, but a system to which the optoelectronic component formed after packaging the optoelectronic element is applied is a high-impedance network system, there exists a serious impedance mismatch. In other words, there is a relatively large difference value between a bandwidth for transmitting a signal by the optoelectronic component and a bandwidth for transmitting a signal by the optoelectronic element. For example, the bandwidth for transmitting the signal by the optoelectronic element is 25 GHz, while the bandwidth for transmitting the signal by the optoelectronic component is 20 GHz.

In a current solution, a resistor capacitor (RC) circuit is connected in parallel between a positive electrode and a negative electrode of an optoelectronic element to increase energy of a high-frequency signal. This implements a function similar to that of a continuous time linear equalizer (CTLE), so as to increase an overall signal transmission bandwidth of an optoelectronic component. However, in this solution, because a capacitor and a resistor are used for low-pass filtering, an absolute value of energy of an actual high-frequency signal remains unchanged, but only an energy ratio of the high-frequency signal is increased compared with an energy ratio of a low-frequency signal. Therefore, a bandwidth loss for transmitting a signal by the optoelectronic component is still larger than that in a bandwidth for transmitting a signal by the optoelectronic element.

### SUMMARY

Embodiments of this application provide an optoelectronic component and a fabrication method thereof, to increase a bandwidth for transmitting a signal by an optoelectronic component formed after packaging.

According to a first aspect, an embodiment of this application provides an optoelectronic component. The optoelectronic component includes a capacitor, an inductor, a carrier component, and an optoelectronic element, where the capacitor, the inductor, and the optoelectronic element are all disposed on the carrier component. The inductor and the capacitor are configured to form a resonant circuit, where a resonance frequency of the resonant circuit is correlated with a signal output frequency of the optoelectronic element. A first electrode of the optoelectronic element is connected to a first electrode of the carrier component through the inductor, and a second electrode of the optoelectronic element is connected to a second electrode of the carrier component. A first electrode of the capacitor is connected to the first electrode of the carrier component, and a second electrode of the capacitor is connected to the second electrode of the carrier component.

In this implementation, the capacitor and the inductor in the optoelectronic component form the resonant circuit; and when the resonance frequency generated by the resonant circuit is made to be relatively close to the signal output frequency of the optoelectronic element by selecting values of the capacitor and the inductor, a resonance signal excites a signal transmitted by the optoelectronic element. This increases a bandwidth for transmitting a signal by the optoelectronic component formed after packaging.

Optionally, in some possible implementations, the inductor includes a wire inductor, the first electrode of the optoelectronic element is connected to one end of the wire inductor, and the other end of the wire inductor is connected to the first electrode of the carrier component. Both ends of the wire inductor are separately connected to the first electrode of the optoelectronic element and the first electrode of the carrier component. This improves feasibility of this solution.

Optionally, in some possible implementations, the inductor includes a wire inductor, the first electrode of the optoelectronic element is connected to one end of the wire inductor, and the other end of the wire inductor is connected to the first electrode of the capacitor. In the implementations of this application, another specific implementation in which the first electrode of the optoelectronic element is connected to the first electrode of the carrier component through the inductor is provided. To be specific, the first electrode of the optoelectronic element is connected to the first electrode of the capacitor through the inductor, and the first electrode of the capacitor is connected to the first electrode of the carrier component. Therefore, the first electrode of the optoelectronic element is also connected to the first electrode of the carrier component. A height of the capacitor is closer to a height of the optoelectronic element. Therefore, a length of the wire inductor connecting the optoelectronic element to the capacitor can be shorter than that of the wire inductor connecting the optoelectronic element to the carrier component. Therefore, the wire inductor used has a shorter length, effectively reducing implementation costs of this solution.

Optionally, in some possible implementations, there are one or more inductors. There may be more than one inductor. Even if an inductor fails, another inductor still works normally. This ensures stability of the optoelectronic component, and improves flexibility of this solution.

Optionally, in some possible implementations, a difference value between the resonance frequency of the resonant circuit and the signal output frequency of the optoelectronic element falls within a preset value range. By ensuring that the resonance frequency of the resonant circuit is relatively close to the signal output frequency of the optoelectronic element, an excitation effect of the resonance signal on the signal transmitted by the optoelectronic element is achieved.

Optionally, in some possible implementations, the first electrode of the capacitor is located on an upper surface of the capacitor, the second electrode of the capacitor is located on a lower surface of the capacitor, the second electrode of the capacitor is attached to the second electrode of the carrier component, and the first electrode of the capacitor is connected to the first electrode of the carrier component through wire bonding. In this capacitor structure, the first electrode and the second electrode of the capacitor are separately located on the upper surface and the lower surface of the capacitor, the lower surface is attached to the second electrode of the carrier component, and the upper surface is connected to the first electrode of the carrier component through wire bonding. In this way, feasibility of this solution is improved.

Optionally, in some possible implementations, both the first electrode of the capacitor and the second electrode of the capacitor are located on a lower surface of the capacitor, the first electrode of the capacitor is attached to the first electrode of the carrier component, and the second electrode of the capacitor is attached to the second electrode of the carrier component. In the capacitor, both electrodes of the capacitor are located on the lower surface of the capacitor, and both electrodes are separately connected to the first electrode and the second electrode of the carrier component in an attachment manner. Compared with the foregoing capacitor structure, a step of wire bonding is skipped, so that a resonance effect generated by the resonant circuit is better.

Optionally, in some possible implementations, the first electrode of the capacitor and the second electrode of the capacitor are separately located at two ends of the capacitor, the first electrode of the capacitor is attached to the first electrode of the carrier component, and the second electrode of the capacitor is attached to the second electrode of the carrier component. This capacitor structure may be a capacitor formed by a common thin-film through welding, improving practicability of this solution.

Optionally, in some possible implementations, the second electrode of the capacitor is located on a lower surface of the capacitor, the second electrode of the capacitor is attached to the second electrode of the carrier component. The first electrode of the capacitor includes a first conductive plating layer, a second conductive plating layer, and a third conductive plating layer, where the first conductive plating layer is located on the lower surface of the capacitor, the second conductive plating layer is located on an upper surface of the capacitor, and the third conductive plating layer is connected to the first conductive plating layer and the second conductive plating layer. The first conductive plating layer is attached to the first electrode of the carrier component, and the other end of the wire inductor is connected to the second conductive plating layer.

In the implementations of this application, the other capacitor structure is provided. Based on such a capacitor, one end of the inductor is connected to the first electrode of the optoelectronic element, and the other end of the inductor is connected to the upper surface of the capacitor. The first electrode of the capacitor covers both the upper surface and a part of the lower surface, and a part that is of the first electrode and a part that is located on the lower surface of the capacitor is attached to the first electrode of the carrier component. Therefore, the first electrode of the optoelectronic element may also be connected to the first electrode of the carrier component through the inductor. In addition, because the height of the capacitor is closer to the height of the optoelectronic element, the length of the wire inductor connecting the optoelectronic element to the capacitor can be shorter than that of the wire inductor connecting the optoelectronic element to the carrier component. Therefore, the wire inductor used has a shorter length, effectively reducing the implementation costs of this solution.

Optionally, in some possible implementations, the carrier component further includes a drive component, where the drive component includes a drive circuit and a bias circuit. The first electrode of the carrier component is connected to a first electrode of the drive circuit and a first electrode of the bias circuit, and the second electrode of the carrier component is connected to a second electrode of the drive circuit and a second electrode of the bias circuit.

Optionally, in some possible implementations, the carrier component further includes a carrier, an insulation base, a circuit board, a first lead, and a second lead, where the capacitor, the inductor, and the optoelectronic element are all disposed on the carrier, the drive circuit and the bias circuit are disposed on the circuit board, the carrier is fastened on the insulation base, the first electrode of the carrier component is connected to the first electrodes of the drive circuit and the bias circuit that are on the circuit board through the first lead, and the second electrode of the carrier component is connected to the second electrodes of the drive circuit and the bias circuit that are on the circuit board through the second lead.

Optionally, in some possible implementations, transistor outline (TO) packaging, chip on board (COB) packaging, or box (BOX) packaging is used for the optoelectronic component. A plurality of possible packaging manners are provided, thereby improving diversity of application scenarios of this solution.

According to a second aspect, an embodiment of this application provides a fabrication method of an optoelectronic component, including:

providing a carrier component, an optoelectronic element, an inductor, and a capacitor;

disposing the optoelectronic element and the capacitor on the carrier component;

connecting a first electrode of the optoelectronic element to a first electrode of the carrier component through the inductor, and connecting a second electrode of the optoelectronic element to a second electrode of the carrier component; and

connecting a first electrode of the capacitor to the first electrode of the carrier component, and connecting a second electrode of the capacitor to the second electrode of the carrier component, where the inductor and the capacitor are configured to form a resonant circuit, and a resonance frequency of the resonant circuit is correlated with a signal output frequency of the optoelectronic element.

Optionally, in some possible implementations, the inductor includes a wire inductor. The connecting a first electrode of the optoelectronic element to a first electrode of the carrier component through the inductor includes: connecting the first electrode of the optoelectronic element to one end of the wire inductor, and connecting the other end of the wire inductor to the first electrode of the carrier component.

Optionally, in some possible implementations, the inductor includes a wire inductor. The connecting a first electrode of the optoelectronic element to a first electrode of the carrier component through the inductor includes: connecting the first electrode of the optoelectronic element to one end of the wire inductor, and connecting the other end of the wire inductor to the first electrode of the capacitor.

Optionally, in some possible implementations, there are one or more inductors.

Optionally, in some possible implementations, a difference value between the resonance frequency of the resonant circuit and the signal output frequency of the optoelectronic element falls within a preset value range.

Optionally, in some possible implementations, the first electrode of the capacitor is located on an upper surface of the capacitor, the second electrode of the capacitor is located on a lower surface of the capacitor. The connecting a first electrode of the capacitor to the first electrode of the carrier component, and connecting a second electrode of the capacitor to the second electrode of the carrier component includes: attaching the second electrode of the capacitor to the second electrode of the carrier component, and connecting the first electrode of the capacitor to the first electrode of the carrier component through wire bonding.

Optionally, in some possible implementations, both the first electrode of the capacitor and the second electrode of the capacitor are located on a lower surface of the capacitor. The connecting a first electrode of the capacitor to the first electrode of the carrier component, and connecting a second electrode of the capacitor to the second electrode of the carrier component includes: connecting the first electrode of the capacitor to the first electrode of the carrier component in an attachment manner, and attaching the second electrode of the capacitor to the second electrode of the carrier component.

Optionally, in some possible implementations, the first electrode of the capacitor and the second electrode of the capacitor are separately located at two ends of the capacitor. The connecting a first electrode of the capacitor to the first electrode of the carrier component, and connecting a second electrode of the capacitor to the second electrode of the carrier component includes: attaching the first electrode of the capacitor to the first electrode of the carrier component, and attaching the second electrode of the capacitor to the second electrode of the carrier component.

Optionally, in some possible implementations, the second electrode of the capacitor is located on a lower surface of the capacitor, and the first electrode of the capacitor includes a first conductive plating layer, a second conductive plating layer, and a third conductive plating layer, where the first conductive plating layer is located on the lower surface of the capacitor, the second conductive plating layer is located on an upper surface of the capacitor, and the third conductive plating layer is connected to the first conductive plating layer and the second conductive plating layer. The connecting a first electrode of the capacitor to the first electrode of the carrier component, and connecting a second electrode of the capacitor to the second electrode of the carrier component includes: attaching the second electrode of the capacitor to the second electrode of the carrier component, attaching the first conductive plating layer to the first electrode of the carrier component, and connecting the other end of the wire inductor to the second conductive plating layer.

Optionally, in some possible implementations, the carrier component further includes a drive component, where the drive component includes a drive circuit and a bias circuit. The method further includes: connecting the first electrode of the carrier component to a first electrode of the drive circuit and a first electrode of the bias circuit, and connecting the second electrode of the carrier component to a second electrode of the drive circuit and a second electrode of the bias circuit.

Optionally, in some possible implementations, the carrier component further includes a carrier, an insulation base, a circuit board, a first lead, and a second lead. The method further includes:

disposing all of the capacitor, the inductor, and the optoelectronic element on the carrier, disposing the drive circuit and the bias circuit on the circuit board, fastening the carrier on the insulation base, connecting the first electrode of the carrier component to the first electrodes of the drive circuit and the bias circuit that are on the circuit board through the first lead, and connecting the second electrode of the carrier component to the second electrodes of the drive circuit and the bias circuit that are on the circuit board through the second lead.

Optionally, in some possible implementations, transistor outline packaging, chip on board packaging, or box packaging is used for the optoelectronic component.

According to a third aspect, an embodiment of this application provides an optoelectronic system, including the optoelectronic component, the drive circuit, and the bias circuit that are described according to any one of the first aspect or the implementations of the first aspect, where a first electrode of the drive circuit is connected to a first electrode of a carrier component, and a second electrode of the drive circuit is connected to a second electrode of the carrier component; and a first electrode of the bias circuit is connected to the first electrode of the carrier component, and a second electrode of the bias circuit is connected to the second electrode of the carrier component.

It can be learned from the foregoing technical solutions that the embodiments of this application have the following advantages: The capacitor and the inductor in the optoelectronic component form the resonant circuit. When the resonance frequency generated by the resonant circuit is relatively close to the signal output frequency of the optoelectronic element, the resonance signal excites the signal transmitted by the optoelectronic element. This increases the bandwidth for transmitting the signal by the optoelectronic component.

### BRIEF DESCRIPTION OF DRAWINGS

FIG. 1 is a schematic spectrum diagram of signals transmitted by an optoelectronic element;

FIG. 2 is a schematic spectrum diagram of signals transmitted by a device formed after packaging an optoelectronic element in the prior art;

FIG. 3 is a schematic structural diagram of a first type of optoelectronic component according to an embodiment of this application;

FIG. 4 is a schematic diagram of a circuit model of an optoelectronic component according to an embodiment of this application;

FIG. 5 is a schematic structural diagram of a second type of optoelectronic component according to an embodiment of this application;

FIG. 6 is a first schematic structural diagram of a capacitor according to an embodiment of this application;

FIG. 7 is a schematic structural diagram of a third type of optoelectronic component according to an embodiment of this application;

FIG. 8 is a second schematic structural diagram of a capacitor according to an embodiment of this application;

FIG. 9 is a third schematic structural diagram of a capacitor according to an embodiment of this application;

FIG. 10 is a fourth schematic structural diagram of a capacitor according to an embodiment of this application;

FIG. 11 is a schematic structural diagram of a fourth type of optoelectronic component according to an embodiment of this application;

FIG. 12 is a schematic structural diagram of a fifth type of optoelectronic component according to an embodiment of this application;

FIG. 13 is a schematic structural diagram of a sixth type of optoelectronic component according to an embodiment of this application; and

FIG. 14 is a schematic diagram of an embodiment of a fabrication method of an optoelectronic component according to an embodiment of this application.

### DESCRIPTION OF EMBODIMENTS

The embodiments of this application provide an optoelectronic component and a fabrication method thereof, to increase a bandwidth for transmitting a signal by an optoelectronic component. It should be noted that the terms “first”, “second”, “third”, “fourth”, and the like in the specification, claims, and accompanying drawings of this application are used to distinguish between similar objects, but do not limit a specific sequence or sequence. It should be understood that the data termed in such a way are interchangeable in proper circumstances so that the embodiments of this application can be implemented in other orders than the order illustrated or described herein. Moreover, the terms “include”, “have”, or any other variant thereof are intended to cover a non-exclusive inclusion. For example, a process, method, system, product, or device that includes a list of steps or units is not necessarily limited to those steps or units, but may include other steps or units not expressly listed or inherent to such a process, method, system, product, or device.

An optoelectronic element in the embodiments of this application may specifically be a semiconductor light emitting diode, a semiconductor laser, or the like that serves as a light source of an information carrier. For example, the optoelectronic element may include a laser diode (LD), a directly modulated semiconductor laser (DML), a distributed feedback laser (DFB), an electro-absorption modulated laser (EML), or a Fabry-Perot laser (FP).

The optoelectronic component in the embodiments of this application is a component with stable functional performance that is formed by an optoelectronic element through electric coupling, device fixation, sealing, or the like. Common packaging forms of for the optoelectronic component include transistor outline packaging, box packaging, and chip on board packaging. Specifically, the optoelectronic component may be a transmitter optical subassembly (TOSA), a receiver optical subassembly (ROSA), a bidirectional optical subassembly (BOSA), or the like.

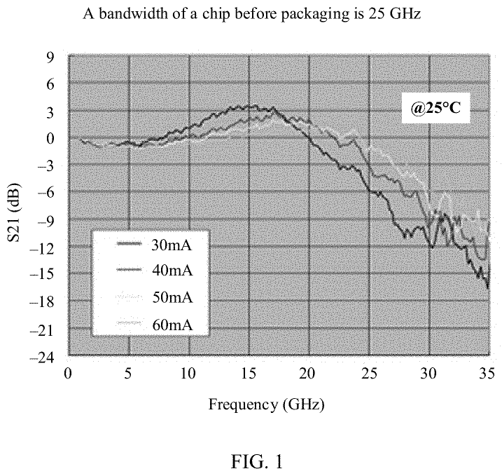

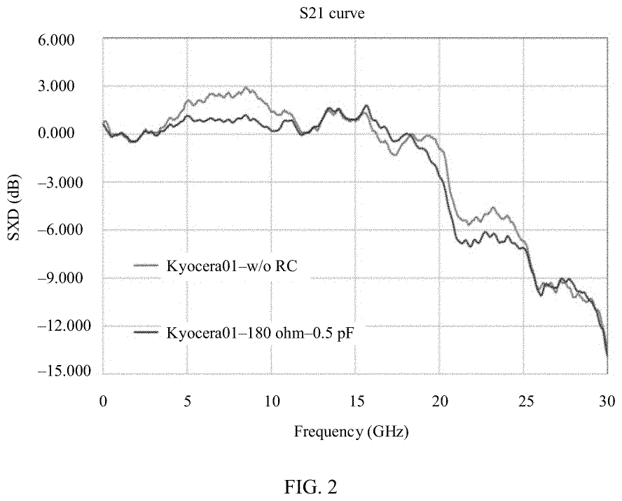

Because an impedance of the optoelectronic element is relatively low, but a system to which the optoelectronic component formed after packaging the optoelectronic element is applied is a high-impedance network system, there exists a serious impedance mismatch. In addition, a size of the optoelectronic element is usually relatively small, and therefore there exists a mode field mismatch during electric coupling. Moreover, various parasitic parameters are introduced due to use of a carrier, a gold wire, a matching network, and the like in a packaging process of the optoelectronic element. In conclusion, there is usually a relatively large difference between a bandwidth for transmitting a signal by the component formed after packaging the optoelectronic element and a bandwidth for transmitting a signal by the optoelectronic element. For example, a 3 dB bandwidth for transmitting a signal by the optoelectronic element before packaging is 25 GHz (as shown in FIG. 1), while a 3 dB bandwidth for transmitting a signal by the optoelectronic component formed by packaging the optoelectronic element is 20 GHz (as shown in FIG. 2) As a result, the bandwidth loss for transmitting a signal by the optoelectronic component is larger than that in a bandwidth of the bandwidth for transmitting a signal by the optoelectronic element.

Therefore, this application provides an optoelectronic component, to increase a bandwidth for transmitting a signal by an optoelectronic component formed after packaging.

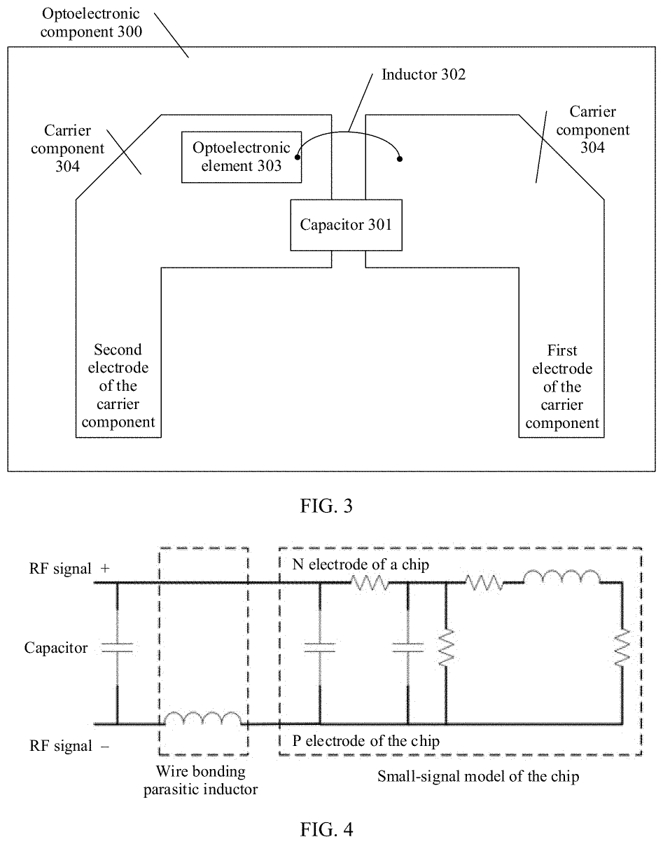

FIG. 3 is a schematic structural diagram of a first type of optoelectronic component according to an embodiment of this application. As shown in FIG. 3, the optoelectronic component 300 includes a capacitor 301, an inductor 302, an optoelectronic element 303, and a carrier component 304. The capacitor 301, the inductor 302, and the optoelectronic element 303 are all disposed on the carrier component 304. It can be understood that each of the capacitor 301, the optoelectronic element 303, and the carrier component 304 includes a positive electrode and a negative electrode. In all the embodiments of this application, a first electrode and a second electrode are used to respectively represent the positive electrode and the negative electrode of each of the foregoing devices. Specifically, if the first electrode represents a positive electrode, the second electrode represents a negative electrode, and vice versa.

The following describes in detail a connection manner between the devices in the optoelectronic component with reference to FIG. 3.

A first electrode of the optoelectronic element 303 is connected to a first electrode of the carrier component 304 through the inductor 302. Specifically, the first electrode of the optoelectronic element 303 is connected to one end of the inductor 302, and the other end of the inductor 302 is connected to the first electrode of the carrier component 304. A second electrode of the optoelectronic element 303 is connected to a second electrode of the carrier component 304. A first electrode and a second electrode of the capacitor 301 are separately connected to the first electrode and the second electrode of the carrier component 304.

It can be understood that the inductor 302 and the capacitor 301 are configured to form a resonant circuit, and a resonance frequency generated by the resonant circuit is correlated with a signal output frequency of the optoelectronic element 303. Specifically, that the resonance frequency is relatively close to the signal output frequency of the optoelectronic element 303 needs to be ensured, that is, a difference value between the resonance frequency and the signal output frequency of the optoelectronic element 303 falls within a preset value range. The preset value range may specifically be plus or minus 5 GHz or a smaller range. If values of the resonance frequency and the signal output frequency of the optoelectronic element 303 are closer to each other, a resonance effect is better.

It should be noted that in this solution, connections between the devices in the optoelectronic component may be direct connections between the devices in a physical location relationship. For example, an electrode located on a lower surface of the optoelectronic element 303 or the capacitor 301 may be connected to an electrode of the carrier component 304 in an attachment manner through welding. Alternatively, connections between the devices in the optoelectronic component may be electrical connections between the devices, that is, different devices may be electrically connected to each other through a connection, where the connection is not necessarily a direct connection in a physical location relationship.

In this embodiment of this application, the capacitor and the inductor in the optoelectronic component form the resonant circuit; and when the resonance frequency generated by the resonant circuit is made to be relatively close to the signal output frequency of the optoelectronic element by selecting values of the capacitor and the inductor, a resonance signal can excite a signal transmitted by the optoelectronic element. This can increase a bandwidth of a bandwidth for transmitting a signal by the optoelectronic component formed after packaging. In addition, no additional load is added to the optoelectronic component, and therefore power consumption of the optoelectronic component is not increased.

Optionally, the inductor 302 may be a wire inductor that may specifically be made of a gold wire. The second electrode of the optoelectronic element 303 may be disposed on the lower surface of the optoelectronic element, the first electrode of the optoelectronic element 303 may be disposed on an upper surface of the optoelectronic element, the lower surface of the optoelectronic element 303 may be connected to the second electrode of the carrier component 304 in an attachment manner, and the upper surface of the optoelectronic element 303 may be connected to the first electrode of the carrier component 304 through wire bonding.

Optionally, there may be one or more inductors 302. When a plurality of inductors are used, one end of each inductor is connected to the first electrode of the optoelectronic element, and the other end of the inductor is connected to the first electrode of the carrier component. This brings an advantage that even if one of the inductors fails, another inductor can still work normally, thereby improving stability of the optoelectronic component.

FIG. 4 is a circuit model diagram according to this application. In FIG. 4, a small-signal model of a chip is a circuit model of the optoelectronic element 303 in this application. Output power of the chip may be calculated according to the following formula:

$${P}_{c h i p} ( ω ) = {( \frac{R}{R + j ω L} )}^{2} \times \frac{{U}_{d r i v e r}^{2}}{R}$$

Output power of the optoelectronic component 300 may be calculated according to the following formula:

$${P}_{chip}^{′} ( ω ) = {( \frac{\frac{1}{j ω C}}{R + j ω L + \frac{1}{j ω C}} )}^{2} \times \frac{{U}_{d r i v e r}^{2}}{R}$$

ω is an angular frequency and is equal to 2πf; R is a resistance of the optoelectronic element; and L is an inductance, C is a capacitance, U_{driver} is a fixed drive voltage, and f is a frequency.

A calculation formula of a resonance frequency fₒ is as follows:

$${f}_{0} = \frac{1}{2 π \sqrt{L C}}$$

When an output frequency of the optoelectronic element is known, the resonance frequency of the resonant circuit is made to be the same as or close to the signal output frequency of the optoelectronic element by selecting values of the inductor and the capacitor. This increases the bandwidth of the bandwidth for transmitting the signal by the optoelectronic component.

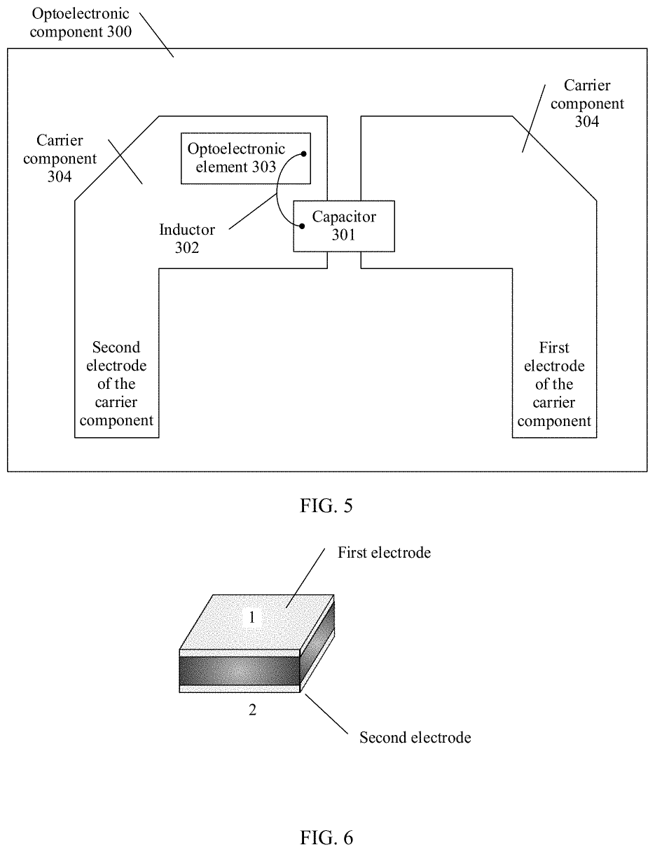

In addition to the connection manner shown in FIG. 3, there may be another connection manner between the devices in the optoelectronic component 300 in the embodiments of this application. FIG. 5 shows a second type of optoelectronic component 300 according to an embodiment of this application. As shown in FIG. 5, the optoelectronic component 300 includes a capacitor 301, an inductor 302, an optoelectronic element 303, and a carrier component 304, where the capacitor 301, the inductor 302, and the optoelectronic element 303 are all disposed on the carrier component 304.

The following describes in detail a connection manner between the devices in the optoelectronic component with reference to FIG. 5.

A first electrode of the optoelectronic element 303 is connected to a first electrode of the carrier component 304 through the inductor 302. Specifically, the first electrode of the optoelectronic element 303 is connected to one end of the inductor 302, and the other end of the inductor 302 is connected to a first electrode of the capacitor 301. A second electrode of the optoelectronic element 303 is connected to a second electrode of the carrier component 304. The first electrode of the capacitor 301 is connected to the first electrode of the carrier component 304, and a second electrode of the capacitor 301 is connected to the second electrode of the carrier component 304.

With reference to the two embodiments shown in FIG. 3 and FIG. 5, the capacitor used in this application may have a plurality of different structures. With reference to several different capacitor structures, the following further describes the embodiments corresponding to FIG. 3 and FIG. 5.

FIG. 6 is a schematic structural diagram of a capacitor according to an embodiment of this application. In the figure, both an upper surface and a lower surface of the capacitor are plating layers as electrodes, the upper surface is corresponding to a first electrode of the capacitor, the lower surface is corresponding to a second electrode of the capacitor, and a middle part of the capacitor is a dielectric medium.

FIG. 7 shows an optoelectronic component 300 provided with the capacitor structure shown in FIG. 6. The second electrode of the capacitor 301 may be connected to the second electrode of the carrier component 304 in an attachment manner through welding, and the first electrode of the capacitor 301 may be connected to the first electrode of the carrier component 304 through wire bonding.

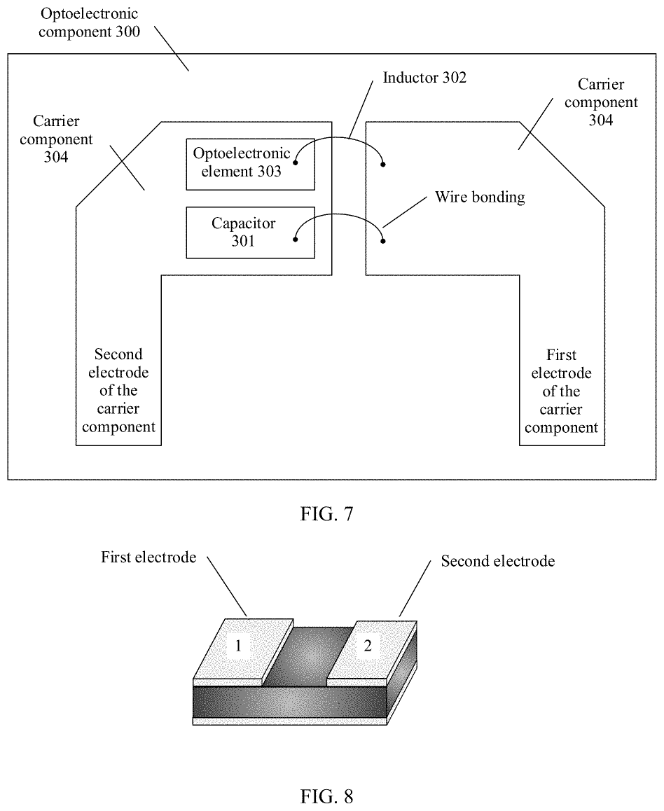

FIG. 8 is another schematic structural diagram of a capacitor according to an embodiment of this application. As shown in FIG. 8, both a first electrode and a second electrode of the capacitor are located on a surface of the capacitor on a same side. In a possible implementation, the first electrode and the second electrode of the capacitor are separately connected to the first electrode and the second electrode of the carrier component in an attachment manner through welding. This may specifically be corresponding to the implementation shown in FIG. 3. Compared with the capacitor structure shown in FIG. 6, in this capacitor structure shown in FIG. 8, there is no need to perform wire bonding to connect the first electrode of the capacitor to the first electrode of the carrier component, so that a resonance effect generated by the resonant circuit is better.

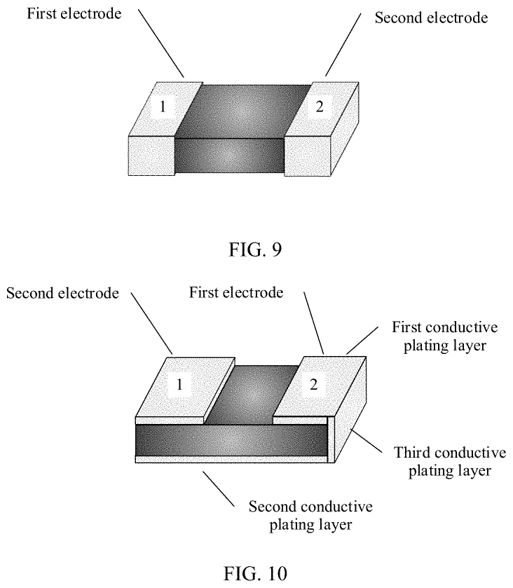

FIG. 9 is another schematic structural diagram of a capacitor according to an embodiment of this application. As shown in FIG. 9, a first electrode and a second electrode of the capacitor are separately located at two ends of the capacitor, and a middle part of the capacitor is a dielectric medium. Different from the capacitor structures, shown in FIG. 6 and FIG. 8, including three layers, namely an upper layer, a middle layer, and a lower layer, FIG. 9 shows a capacitor structure including three layers: namely a left layer, a middle layer, and a right layer, is shown in FIG. 9. The first electrode of the capacitor may be attached to the first electrode of the carrier component through welding, and the second electrode of the capacitor may also be attached to the second electrode of the carrier component through welding. This may specifically be corresponding to the implementation shown in FIG. 3.

FIG. 10 is another schematic structural diagram of a capacitor according to an embodiment of this application. As shown in FIG. 10, a second electrode of the capacitor is located on one surface of the capacitor, and the second electrode of the capacitor may be attached to the second electrode of the carrier component through welding. The first electrode of the capacitor may be divided into three parts, namely a first conductive plating layer, a second conductive plating layer, and a third conductive plating layer. The first conductive plating layer and the second electrode of the capacitor are located on a same surface, the second conductive plating layer is located on another surface opposite to the first conductive plating layer, and the third conductive plating layer is located on a side surface of the capacitor and is connected to the first conductive plating layer and As a whole, the first conductive plating layer and the second conductive plating layer are electrically connected to each other. Therefore, the first conductive plating layer may be attached to the first electrode of the carrier component through welding, one end of the wire inductor is connected to the first electrode of the optoelectronic element, and the other end of the wire inductor is connected to the second conductive plating layer. In this way, the first electrode of the optoelectronic element and the first electrode of the carrier component are electrically connected to each other. This is specifically corresponding to the implementation shown in FIG. 5.

In the capacitor structure shown in FIG. 10, a height of the capacitor is relatively closer to a height of the optoelectronic element. Therefore, a length of the wire inductor connecting the optoelectronic element to the capacitor can be shorter than that of the wire inductor connecting the optoelectronic element to the carrier component. This effectively reduces implementation costs of the optoelectronic component.

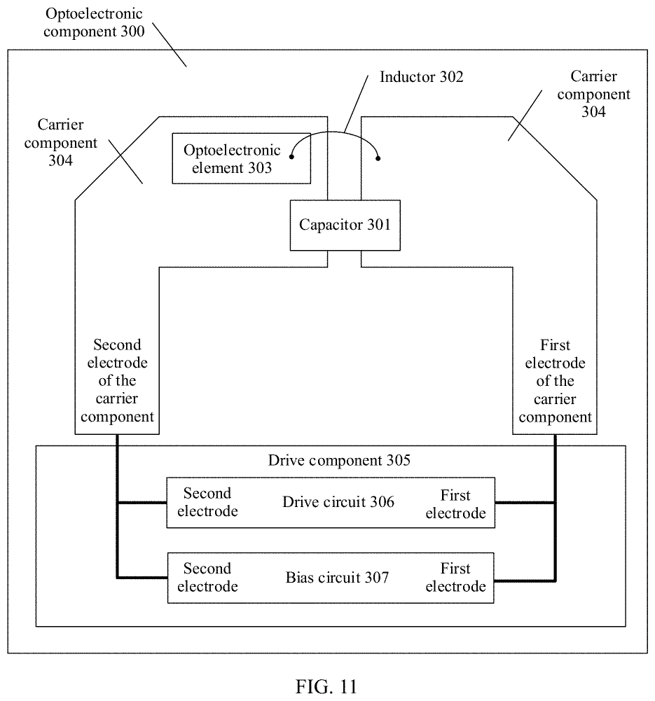

The following further describes composition of the carrier component 304 in the optoelectronic component 300. FIG. 11 shows another optoelectronic component 300 according to an embodiment of this application.

Optionally, the carrier component 304 may further include a drive component 305. The drive component 305 may specifically include a drive circuit 306 and a bias circuit 307. The first electrode of the carrier component 304 is connected to a first electrode of the drive circuit 306 and a first electrode of the bias circuit 307, and the second electrode of the carrier component 304 is connected to a second electrode of the drive circuit 306 and a second electrode of the bias circuit 307.

It should be noted that the optoelectronic element is connected to the capacitor and the inductor, further forming a signal loop with the drive circuit and the bias circuit by using the two electrodes of the carrier component. The bias circuit loads a bias current for the optoelectronic element, so that the optoelectronic element works normally. The drive circuit sends a high-speed radio-frequency signal, and loads the high-speed radio-frequency signal to the optoelectronic element through a positive electrode and a negative electrode of the carrier component, so that the optoelectronic element transmits the high-speed radio-frequency signal.

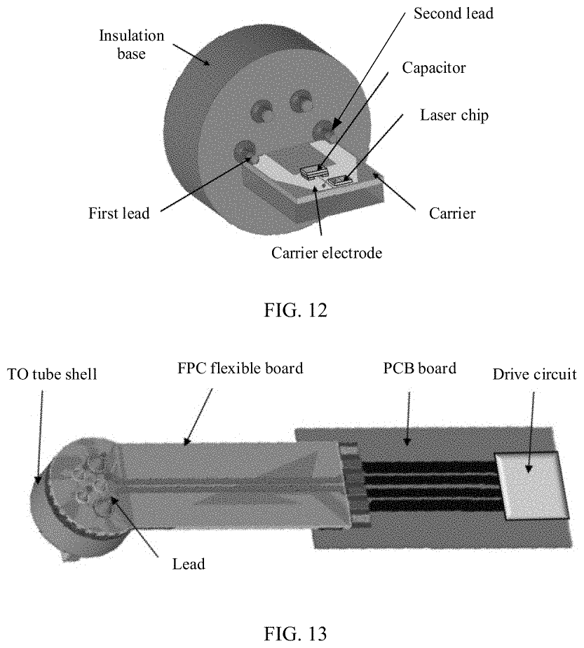

With reference to FIG. 12 and FIG. 13, the following further describes the optoelectronic component shown in FIG. 11. Optionally, the carrier component may specifically include a carrier, an insulation base (a tube shell), a circuit board, a first lead, and a second lead. The capacitor, the inductor, and the optoelectronic element are all disposed on the carrier, the carrier is fastened on the insulation base, the first electrode of the carrier component is connected to the first electrodes of the drive circuit and the bias circuit that are on the circuit board through the first lead, and the second electrode of the carrier component is connected to the second electrodes of the drive circuit and the bias circuit that are on the circuit board through the second lead.

It should be noted that the leads in the carrier component include but are not limited to the first lead and the second lead. Both the drive circuit and the bias circuit may be disposed on the circuit board. As shown in FIG. 12, the circuit board may be placed inside the tube shell provided by the insulation base.

Optionally, the circuit board may extend out from an inner part of the tube shell provided by the insulation base. As shown in FIG. 13, the circuit board may include a flexible printed circuit (FPC) and/or a printed circuit board (PCB).

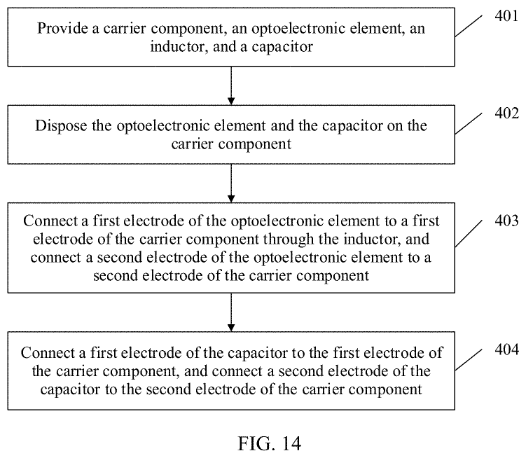

FIG. 14 shows a fabrication method of an optoelectronic component according to an embodiment of this application. As shown in FIG. 14, the method includes the following steps.

401. Provide a carrier component, an optoelectronic element, an inductor, and a capacitor.

402. Dispose the optoelectronic element and the capacitor on the carrier component.

403. Connect a first electrode of the optoelectronic element to a first electrode of the carrier component through the inductor, and connect a second electrode of the optoelectronic element to a second electrode of the carrier component.

404. Connect a first electrode of the capacitor to the first electrode of the carrier component, and connect a second electrode of the capacitor to the second electrode of the carrier component.

In this embodiment of this application, the capacitor and the inductor are configured to form a resonant circuit; and when a resonance frequency generated by the resonant circuit is made to be relatively close to a signal output frequency of the optoelectronic element by selecting values of the capacitor and the inductor, a resonance signal excites a signal transmitted by the optoelectronic element. This increases a bandwidth of a bandwidth for transmitting a signal by the optoelectronic component formed after packaging.

It should be noted that a sequence of the foregoing processing steps is not specifically limited in this application. Specifically, in this embodiment of this application, the optoelectronic component may be fabricated according to the structures of the optoelectronic components in the embodiments shown in FIG. 3 to FIG. 13. Details are not described herein again.

It should be noted that the foregoing embodiments are merely intended to describe the technical solutions of this application other than to limit this application. Although this application is described in detail with reference to the foregoing embodiments, a person of ordinary skill in the art should understand that modifications may still be made to the technical solutions described in the foregoing embodiments or equivalent replacements may still be made to some technical features thereof, without departing from the spirit and scope of the technical solutions of the embodiments of this application.

1. An optoelectronic component, comprising:
a capacitor, an inductor, a carrier component, and an optoelectronic element, wherein:
the capacitor, the inductor, and the optoelectronic element are disposed on the carrier component;
the inductor and the capacitor are configured to form a resonant circuit, wherein a resonance frequency of the resonant circuit is correlated with a signal output frequency of the optoelectronic element;
a first electrode of the optoelectronic element is connected to a first electrode of the carrier component through the inductor, and a second electrode of the optoelectronic element is connected to a second electrode of the carrier component; and
a first electrode of the capacitor is connected to the first electrode of the carrier component, and a second electrode of the capacitor is connected to the second electrode of the carrier component.

2. The optoelectronic component according to claim 1, wherein the inductor comprises a wire inductor, the first electrode of the optoelectronic element is connected to one end of the wire inductor, and the other end of the wire inductor is connected to the first electrode of the carrier component.

3. The optoelectronic component according to claim 1, wherein the inductor comprises a wire inductor, the first electrode of the optoelectronic element is connected to one end of the wire inductor, and the other end of the wire inductor is connected to the first electrode of the capacitor.

4. The optoelectronic component according to claim 1, wherein a difference value between the resonance frequency of the resonant circuit and the signal output frequency of the optoelectronic element falls within a preset value range; or the resonance frequency of the resonant circuit is equal to the signal output frequency of the optoelectronic element.

5. The optoelectronic component according to claim 1, wherein the first electrode of the capacitor is located on an upper surface of the capacitor, the second electrode of the capacitor is located on a lower surface of the capacitor, and the first electrode of the capacitor is connected to the first electrode of the carrier component through wire bonding.

6. The optoelectronic assembly according to claim 1, wherein both the first electrode of the capacitor and the second electrode of the capacitor are located on a lower surface of the capacitor.

7. The optoelectronic component according to claim 1, wherein the first electrode of the capacitor and the second electrode of the capacitor are located at first and second ends of the capacitor, respectively.

8. The optoelectronic component according to claim 1, wherein the second electrode of the capacitor is located on a lower surface of the capacitor;
the first electrode of the capacitor comprises a first conductive plating layer, a second conductive plating layer, and a third conductive plating layer, wherein the first conductive plating layer is located on the lower surface of the capacitor, the second conductive plating layer is located on an upper surface of the capacitor, and the third conductive plating layer is connected to the first conductive plating layer and the second conductive plating layer; and
the first conductive plating layer is attached to the first electrode of the carrier component, and an end of a wire inductor is connected to the second conductive plating layer.

9. The optoelectronic component according to claim 1, wherein the carrier component further comprises a drive component, and the drive component comprises a drive circuit and a bias circuit; and
the first electrode of the carrier component is connected to a first electrode of the drive circuit and a first electrode of the bias circuit, and the second electrode of the carrier component is connected to a second electrode of the drive circuit and a second electrode of the bias circuit.

10. The optoelectronic component according to claim 9, wherein the carrier component further comprises a carrier, an insulation base, a circuit board, a first lead, and a second lead, wherein:
the capacitor, the inductor, and the optoelectronic element are disposed on the carrier, a drive circuit and a bias circuit are disposed on the circuit board, the carrier is fastened to the insulation base, the first electrode of the carrier component is connected to the first electrodes of the drive circuit and the bias circuit through the first lead, and the second electrode of the carrier component is connected to the second electrodes of the drive circuit and the bias circuit through the second lead.

11. The optoelectronic component according to claim 10, wherein transistor outline packaging, chip on board packaging, or box packaging is used for the optoelectronic component.

12. A fabrication method of an optoelectronic component, wherein the method comprises:
disposing an optoelectronic element and a capacitor on a carrier component;
connecting a first electrode of the optoelectronic element to a first electrode of the carrier component through an inductor, and connecting a second electrode of the optoelectronic element to a second electrode of the carrier component; and
connecting a first electrode of the capacitor to the first electrode of the carrier component, and connecting a second electrode of the capacitor to the second electrode of the carrier component, wherein the inductor and the capacitor are configured to form a resonant circuit, and a resonance frequency of the resonant circuit is correlated with a signal output frequency of the optoelectronic element.

13. The method according to claim 12, wherein the inductor comprises a wire inductor, and connecting the first electrode of the optoelectronic element to the first electrode of the carrier component through the inductor comprises:
connecting the first electrode of the optoelectronic element to one end of the wire inductor, and connecting an other end of the wire inductor to the first electrode of the carrier component.

14. The method according to claim 12, wherein the inductor comprises a wire inductor, and connecting the first electrode of the optoelectronic element to the first electrode of the carrier component through the inductor comprises:
connecting the first electrode of the optoelectronic element to one end of the wire inductor, and connecting an other end of the wire inductor to the first electrode of the capacitor.

15. The method according to claim 12, wherein a difference value between the resonance frequency of the resonant circuit and the signal output frequency of the optoelectronic element falls within a preset value range; or the resonance frequency of the resonant circuit is equal to the signal output frequency of the optoelectronic element.

16. The method according to claim 12, wherein the first electrode of the capacitor is located on an upper surface of the capacitor, the second electrode of the capacitor is located on a lower surface of the capacitor; and
connecting a the first electrode of the capacitor to the first electrode of the carrier component, and connecting the second electrode of the capacitor to the second electrode of the carrier component comprises: welding the second electrode of the capacitor to the second electrode of the carrier component, and connecting the first electrode of the capacitor to the first electrode of the carrier component through wire bonding.

17. The method according to claim 12, wherein both the first electrode of the capacitor and the second electrode of the capacitor are located on a lower surface of the capacitor; and
connecting the first electrode of the capacitor to the first electrode of the carrier component, and connecting the second electrode of the capacitor to the second electrode of the carrier component comprises:
welding the first electrode of the capacitor to the first electrode of the carrier component, and welding the second electrode of the capacitor to the second electrode of the carrier component.

18. The method according to claim 12, wherein the first electrode of the capacitor and the second electrode of the capacitor are located at first and second ends of the capacitor, respectively, and
connecting the first electrode of the capacitor to the first electrode of the carrier component, and connecting the second electrode of the capacitor to the second electrode of the carrier component comprises:
welding the first electrode of the capacitor to the first electrode of the carrier component, and welding the second electrode of the capacitor to the second electrode of the carrier component.

19. The method according to claim 12, wherein the second electrode of the capacitor is located on a lower surface of the capacitor, and the first electrode of the capacitor comprises a first conductive plating layer, a second conductive plating layer, and a third conductive plating layer, wherein the first conductive plating layer is located on the lower surface of the capacitor, the second conductive plating layer is located on an upper surface of the capacitor, and the third conductive plating layer is connected to the first conductive plating layer and the second conductive plating layer; and
connecting the first electrode of the capacitor to the first electrode of the carrier component, and connecting the second electrode of the capacitor to the second electrode of the carrier component comprises:
welding the second electrode of the capacitor to the second electrode of the carrier component, welding the first conductive plating layer to the first electrode of the carrier component, and connecting an end of a wire inductor to the second conductive plating layer.

20. The method according to claim 19, wherein the carrier component further comprises a drive component, and the drive component comprises a drive circuit and a bias circuit; and
the method further comprises: connecting the first electrode of the carrier component to a first electrode of the drive circuit and a first electrode of the bias circuit, and connecting the second electrode of the carrier component to a second electrode of the drive circuit and a second electrode of the bias circuit.
